(19) United States
(12) Patent Application Publication
(10) Pub. No.: US 2005/0250052 A1
(43) Pub. Date: Nov. 10, 2005

(54) Maskless lithography using UV absorbing nano particle

(76) Inventor: Khe C. Nguyen, Ho Chi Minh City (VN)

Correspondence Address: TRAN & ASSOCIATES, 6768 MEADOW VISTA CT., SAN JOSE, CA, 95135, US

(21) Appl. No.: 10/843,411

(22) Filed: May 10, 2004

(51) Int. Cl. G03F 7/00

(52) U.S. Cl. 430/322; 430/327

(57) ABSTRACT

Systems and methods are disclosed for a maskless lithography process by over coating a photo resist layer with water soluble thermoplastics; and imaging ultraviolet (UV) absorbing nano particles onto the photo resist layer.

### BACKGROUND

The present invention relates generally to lithographic equipment used in the manufacture of integrated circuit devices.

High-throughput lithography systems are important in the commercial fabrication of microelectronic components. They are used for high-volume production of small-area packages such as integrated circuits as well as large-area patterns such as flat-panel displays. Optical lithography is the most widely used technology for high-volume production because it can achieve high throughput via the parallel nature of its pattern generation, in which a large number of features are simultaneously printed onto a substrate during a single exposure. In conventional analog photolithography systems, the photographic equipment requires a mask for printing an image onto a subject. The subject may include, for example, a photo resist coated semiconductor substrate for manufacture of integrated circuits, metal substrate for etched lead frame manufacture, conductive plate for printed circuit board manufacture, or the like. A patterned mask or photo mask may include, for example, a plurality of lines or structures. During a photolithographic exposure, the subject must be aligned to the mask very accurately using some form of mechanical control and sophisticated alignment mechanism.

Conventional photolithography in wafer processing using a mask and a mask aligner requires an expensive mask making step and an expensive mask aligner. Moreover, contact exposure through the mask can destroy the photosensitive coating layer, depending on the materials used. Further, conventional photolithography may need expensive CEA (contrast enhancement agent) to enhance image contrast. Thus, avoiding the use of masks is desirable to improve the productivity and cost of microelectronic fabrication.

As noted in U.S. Pat. No. 6,238,852, the content of which is incorporated by reference, various projection imaging systems are used in fabrication of microelectronic modules. Single-field, or conventional, projection tools are those in which the image field of the lens is sufficient to accommodate the entire substrate. Typically, a projection lens with a 1:1 magnification is used. For different design resolutions, the maximum image field size of the projection lens is different: whereas a 1 mil resolution can be obtained over a 4 inch square field, the imageable area for 1 micron resolution must be limited to a field diameter no larger than 2-3 cm. Thus, conventional projection printing systems are limited by the fundamental trade-off between the desired resolution and the largest substrate they can image. In a step-and-repeat type of projection system, the total substrate area to be patterned is broken up into several segments, which segments are then imaged one at a time by stepping the substrate under the lens from one segment to the next. Due to the increased overhead time required for the stepping, settling and aligning steps for each segment, step-and-repeat projection systems deliver low throughputs.

A focused-beam direct-writing system uses a laser in a raster scanning fashion to expose all the pixels, one at a time, on the substrate. To be compatible with the spectral sensitivity of common photo resists, typically an argon-ion laser operating at one or more of its UV or blue wavelengths is employed. The laser beam is focused on the resist-coated substrate to the desired spot size. The focused spot is moved across the substrate in one dimension with a motor-driven scanning mirror. In conjunction, the stage holding the substrate is translated in the orthogonal dimension with a high-precision stepping motor. Simultaneously, the laser beam is modulated (typically, acousto-optically) to be either directed to the desired location on the substrate or deflected away. Thus, by driving the modulator and the two motors with appropriately processed pattern data, the entire substrate can be directly patterned. Of the many focused-beam direct-write systems currently available, the offered resolution varies from several microns for board patterning to under a micron for systems designed for mask-making applications for IC lithography. Since transfer of the pattern information by such tools takes place in a slow, bit-by-bit serial mode, typical substrate exposure times can range from 2 minutes to several hours per sq. ft., depending upon the resolution and the complexity of the pattern data. Although direct write systems do not require the use of masks—and are therefore not subject to many of the effects which limit mask-based technologies—the serial nature of their pattern generation renders direct-write systems significantly lower in throughput compared to contact, proximity, and projection printers.

Holographic imaging systems utilize a mask which is a hologram of the pattern to be imaged, such that when “played back,” it projects the original pattern onto the substrate. The mask is generated by encoding the diffraction pattern from a standard mask in a volume hologram. Generally, for all but the simplest patterns, fabrication of the holographic mask requires numerous processing steps. In a holographic lithography system, the burden of imaging is placed entirely on the mask. Holographic imaging systems suffer from poor diffraction efficiency and are applicable, at best, for imaging of very periodic patterns of not very high resolution. If the pattern is not periodic, the imaging resolution degrades. Holographic masks are also considerably more expensive to generate, which is made further prohibitive when masks for many different layers are required for the substrate.

U.S. Pat. No. 5,691,541, which is hereby incorporated by reference, describes a digital, reticle-free photolithography system. The digital system employs a pulsed or strobe excimer laser to reflect light off a programmable digital mirror device (DMD) for projecting a component image (e.g., a metal line) onto a substrate. The substrate is mounted on a stage that is moves during the sequence of pulses.

U.S. Pat. No. 6,379,867, hereby incorporated by reference, discloses another digital photolithography system which projects a moving digital pixel pattern onto specific sites of a subject. A “site” may represent a predefined area of the subject that is scanned by the photolithography system with a single pixel element.

U.S. Pat. No. 6,473,237, hereby incorporated by reference, discloses a digital lithography system with a non-coherent light source for producing a first light and an optical diffraction element for individually focusing the first light into a plurality of second lights. The system also includes a pixel panel for generating a digital pattern, the pixel panel having a plurality of pixels corresponding to the plurality of second lights. A lens system may then direct the digital pattern to the subject, thereby enabling the lithography.

These digital photolithography systems project a pixel-mask pattern onto a subject such as a wafer, printed circuit board, or other medium. The systems provide a series of patterns to a pixel panel, such as a deformable mirror device or a liquid crystal display. The pixel panel provides images consisting of a plurality of pixel elements corresponding to the provided pattern that may be projected onto the subject. Each of the plurality of pixel elements is then simultaneously focused to different sites of the subject. The subject and pixel elements are then moved and the next image is provided responsive to the movement and responsive to the pixel-mask pattern. As a result, light can be projected onto or through the pixel panel to expose the plurality of pixel elements on the subject, and the pixel elements can be moved and altered, according to the pixel-mask pattern, to create contiguous images on the subject. These systems are expensive to operate and improvements in image resolution are still needed.

During fabrication, a precursor known as diazonapthoquinone (DNQ) is an important component for positive photoresists. The resist is a photo acid generator which can be washed away with an alkaline developer. After development, the photo resist mask made with DNQ and Novolack resin (positive photo resist) has been known to exhibits excellent etch resistance against conventional plasma such as SF6, CF4, O2 or base and acidic wet etching agents such as KOH, TMAH, HF, HCL, for example. The chemical resistance of DNQ/Novolack resin type photo resist mask also exhibits superior etch resistance over other negative resists such as photoimageable polyimide, polymethylmethacrylate (PMMA), silicone based resist, styrene based resist, among others. The DNQ/Novolack type positive photo resist is one of the best masking materials in terms of etch quality, cost issue and environmental safety. Thus, the purpose of the present invention is to maintain the best practice of (DNQ/Novolack) in a maskless lithography process manner so that the current parameters of photolithography still survive except making the masking process more economical and simpler.

Direct writing of photo resist ink using piezoelectric ink jet head onto a patterned surface has been discussed by Kateri E. Paul et al, Appl Phys Lett 83(10) 2070(08 Sep. 2003), the content of which is incorporated by reference. However, the technology works primarily with low viscosity coating for thin resist layers and is unsuitable for high aspect ratio processing. Direct writing of photo resist ink has compatibility issue between the inking resist and printing process and between the inking resist and substrate. Further, nozzle clogging may occur due to resist chemistry instability. Additionally, feature size may be limited due to the nozzle size and printing speed.

Direct writing processes using laser, X-ray, electron beam, ion beam, molecular beam, dip-pen lithography have been used to produce sub micron and nano scale patterns as discussed by G. M, Whitesides et al in Scientific American, September 2001, page 39, the content of which is incorporated by reference. However, the process is slow due to limitations in the current sensitivity of recording materials with the writing head.

### SUMMARY

Systems and methods are disclosed for performing a maskless lithography process by over coating a photo resist layer with water soluble thermoplastics; and depositing UV absorbing nano-particles onto the photo resist layer.

Advantages of the system may include one or more of the following. The system provides ideal and absolute contact exposure. The system provides low cost photolithography without using mask. The system offers shorter processing time due to eliminating the mask making step. The production cost is reduced due to the simplification of the micro fabrication process. The lithography process with the UV absorbing nano-particle is safer than a lithography process using conventional masking materials. The maskless printing simplifies the photolithographic process and is more precise than the process with a mask aligner and stepper. The process is also economical, safe, and results in better lithography than conventional masking process. The system can be used to form thin film structures without using plasma or vacuum technologies. The UV absorbing nano-particles can be prepared into a hydrophilic format to avoid damaging the photo resist layer which is hydrophobic before ultraviolet exposure. The UV absorbing nano particles can be formulated into conventional inks which is well compatible with print head and various kinds of substrate and can be digitally printed by inkjet head, microcontact printing head, nano imprint head, nano molding head, dip pen lithographic head, X ray, e beam, ion beam, molecular beam, laser print head (electrostatic process), or thermo plasticizing, thermo-hardening, and photo-thermohardening process. The UV absorbing nano-particles are hydrophilic so conventional photo resist can be used without corrosive materials or harmful chemicals. The UV absorbing nano-particles can also be made into hydrophobic species so it can be used with suitable organic solvents for various maskless lithographic process. The process can replace or work in conjunction with contrast enhanced materials (CEM). The UV absorbing nano-particles can also be used for proton membrane exchange in a fuel cell.

### BRIEF DESCRIPTION OF THE DRAWINGS

FIG. 1 shows a first exemplary maskless lithography process using ultraviolet (UV) absorbing nano particles.

FIG. 2 shows a second exemplary maskless lithography process using UV absorbing nano particles.

FIG. 3 shows a third exemplary maskless lithography process using UV absorbing nano particles.

FIG. 4 shows a fourth exemplary maskless lithography process using UV absorbing nano particles.

FIG. 5 shows a fifth exemplary maskless lithography process using UV absorbing nano particles.

FIG. 6 shows a sixth exemplary maskless lithography process using UV absorbing nano particles.

FIG. 7 shows a seventh exemplary maskless lithography process using UV absorbing nano particles

FIGS. 8A-8G shows a seventh exemplary maskless lithography process using UV absorbing nano particles

FIGS. 9A and 9B show two embodiments for performing maskless lithography.

FIG. 10A shows an exemplary process for forming liquid nano-carbon.

FIG. 10B shows an exemplary diagram for forming liquid nano-carbon.

FIG. 11 shows another embodiment showing various exemplary steps in maskless lithography.

FIGS. 12-13 show an exemplary application of the nano-particles in a fuel cell.

FIG. 14 shows an exemplary nano-particle printing process.

### DESCRIPTION

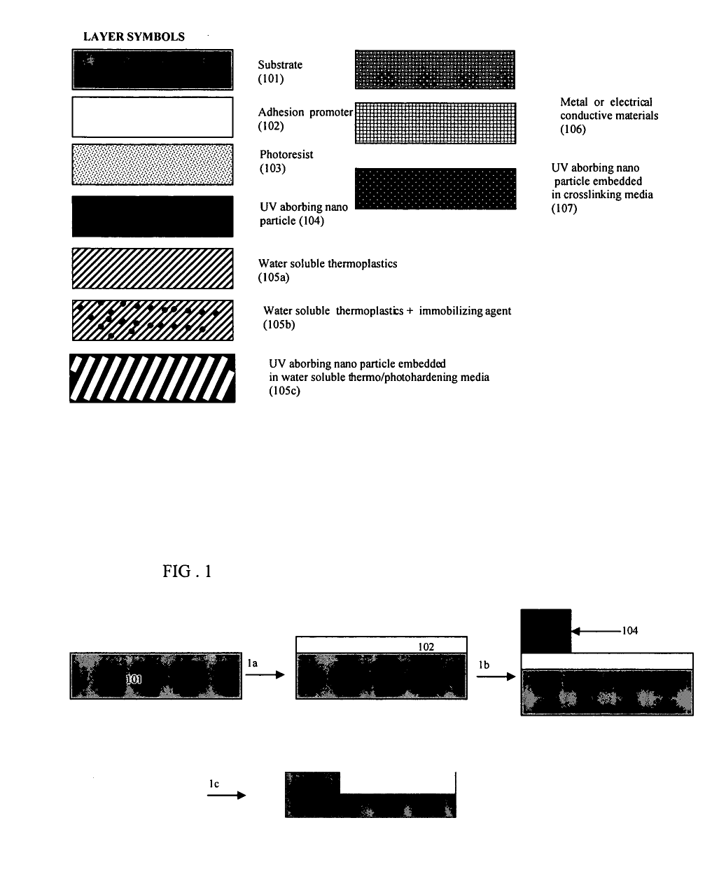

FIG. 1 shows one exemplary process of maskless lithography using nano-particles. The process 1 includes following operations:

1a. spin coat a substrate 101 with an adhesion promoter 102 and dry the substrate 101 with one or more energy sources. In some cases, the adhesion promoter 102 may be skipped.

1b. image UV absorbing nano particles 104 on the promoter 102 and stabilize the imaged nano-particles 104 if necessary using heat, photographic, pressure, air flow, solvent vapor or a combination of energy sources without damaging other components on the substrate 101. In certain embodiments, the UV absorbing nano particle image can go to the next operation without any hard stabilizing process. The UV absorbing nano particles can be printed onto the substrate 101 by a printing mechanism such as an inkjet head, a dip pen lithography head, a microcontact printing head, a micromolding head, a nano imprint head. Alternatively, the printing mechanism can perform charge transfer from photoconductor, or irradiation energy induced electrostatic charge transfer. The printing mechanism can achieve desired feature size such as 1 nm or less.

1c. process the uncovered substrate surface. For example, the process can perform etching of the substrate materials until a desired thickness or surface properties is obtained. In one embodiment, UV absorbing nano particles operates as a mask for the etching or processing of the substrate.

After the completion of operation 1c, the UV absorbing nano particle mask is removed to achieve a desired etched pattern on the substrate 101.

The substrate 101 can be insulative, conductive, semiconductive, superconductive substrates such as glass, metal, metal oxides, semiconductor substance, or a polymer. The substrate can be flexible or rigid. Other suitable substrates include ceramic, metallic or semiconductive, and preferred substrates are silicon-containing, for example, silicon dioxide, silicon nitride, and silicon oxynitride, silicon germanide (SiGe). Other suitable substrates are aluminum oxide (sapphire), sapphire containing Galium Arsenide (GaAs), Indium Phosphite (InP), Galium Nitride (GaN). Other suitable substrates include transparent and/or transparent conductive substrate such as ITO (indium tin oxides), transparent and/or transparent conductive substrate carrying conductive polymers including but not limited to poly aniline, poly thiophene, poly phenyl vinylidene, thin and thick film of organic pigments such as but not limited to perylenes, phthalocyanines, quinacridones, bisazo, bisbenzimidazole, anthanthrone, among others, and inorganic pigment such as CdSe, CdTe, ZnO, TiO2, ZrO2, among others, and chalcogenide glass such as As2Se3, SeTe, SexTeyBiz, among others.

The adhesion promoter 102 is deposited to enhance adhesion between the layers and to minimize the chance that moisture or other impurities to penetrate the seams between the layers, causing corrosion or other impurity-induced phenomena that adversely impacts the performance of an integrated circuit. The nano-particle image 104 is formed above the promoter layer 102. The image can be formed digitally through suitable printing or jetting methods inkjet head, dip pen lithography head, microcontact printing head, micromolding head, nano imprint head, irradiation energy induced electrostatic charge transfer or writing head from high energy sources such as X ray, E beam, ion beam, molecular beam to achieve desired feature size from lnm as discussed in more detail below.

The image can be made with nano particles which absorb the UV, including but not limited to liquid nano-carbon, nano AlO(OH), nano-silica, nano-Al2O3, or nano particles of any oxide materials such as ZnO, TiO2, ZrO2, MgO, nano particles of organic UV absorbers such as anti oxidant agent, anti photo oxidant, UV prohibiter, UV absorbing dye molecules, nano catalysts which can form UV block under irradiation of light or heat. These nano particles can be used in a dry powder form or in a liquid format.

The nano carbon particles can be carbon particles having particles size less than 100 nm including but not limited to carbon nano tube powder, liquid nano carbon, carbon black, graphite and graphene powder, fullerene C60 and C70 powder of which the surface is chemically modified so that it exhibits the reduction of interparticular interaction until a self stabilization is established. The chemical surface modification process also renders an increased surface wetness, the dispersibility and compatibility of nano carbon particles against coating solvents, facilitates the digital ink formulation as well as increase the possibility of thin film forming from conventional wet coating process. The isolation of individual particles and rearranging them on a substrate helps to form a stable thin film without using expensive vacuum technologies. The thin film is prepared by a spin process. Spin coating is one way to obtain sub micron thick film from nano particles and other known coating techniques available for the same purpose can be used, for example dip coating, spray coating, and hopper coating, among others.

For the other materials besides carbon, the nano particles are obtainable through sol-gel process. The raw materials are selected from a liquid product and the thin film is prepared by wet coating (spin, spray, dip, among others) of the in-situ materials. The in-situ material is converted into the target materials using certain kind of energy, followed with further chemical or physical treatment if needed. The energy which converts the in-situ materials into the target materials can be provided by the writing head, so it can write the digital information and the final information carries the target materials needed for next processing operation. The writing energy can be from high energy sources such E beam, ion beam, X ray, gamma ray, among others. Zn(OH)2, Zn carbamate, Zn octoate are examples of in-situ material to form UV absorbing ZnO nano particles on a substrate.

The in-situ materials (for example Zn(OH)2) in liquid format is spun on a wafer to form a thin film. Next, the film is exposed to a high energy source such as E beam to be converted into the target material ZnO due to the chemical reaction
Zn(OH)2=>ZnO+H2O.

The nano ZnO particles formed on the wafer substrate exhibit an increased absorption efficiency of UV. The nano particles form a mask for next processing step of the wafer. In this case, the mask is digitally created by the E beam and there is no need to use mask for photolithography.

Titanium isopropoxide, titanium(IV)2-ethylhexoxide, titanium chloride, Ti2O2(THF)4, titanium diisopropoxide bis(2,4-pentanedionate), titanium propoxide, titanocene dichloride and the likes are examples of in situ materials to form nano particles of TiO2. These chemicals are available from Aldrich Chemical, Inc.

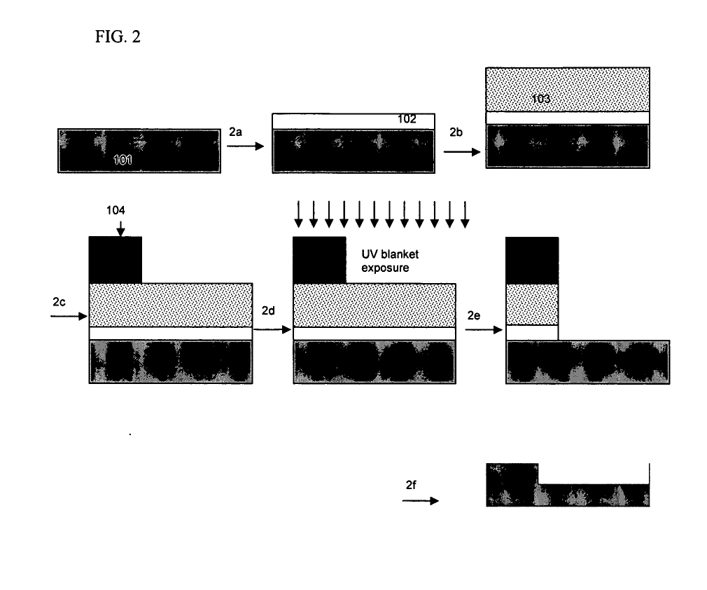

In another embodiment shown in FIG. 2, another maskless lithography process using nano particles includes the following operations:

2a. spin coat the substrate 101 with an adhesion promoter 102 and dry the substrate with energy. In some cases, there is no need to spin the adhesion promoter 102.

2b. spin coat the substrate 101 carrying the adhesion promoter 102 with the photoresist 103 to achieve desired thickness and dry the photoresist layer by a soft bake in an oven set at a predetermined temperature and time depending on the resist thickness and spin coating solvent. In one embodiment, the temperature is set between 60 C and 120 C for a period of time between 1-100 minutes. The photoresist can be selected from a positive resist or a negative resist known to those skilled in the art. In one exemplary embodiment, a positive resist composed of DNQ and Novolak resin is used as a photo acid generator. The photo acid generator can be dissolved in suitable alkaline solution being exposed to UV strongly absorbed by the resist. Acrylate ester polymers such as PMMA (PolymethylMethacrylate) photoimageable polyimide can be used as a positive resist upon exposure to high energy beam such as X-ray or gamma ray, among others. The negative resist tends to cross-link after being exposed to UV and becomes insoluble. The unexposed resist can be washed away with a suitable solvent. The photoresist coating can be applied by a number of known coating techniques such as spinning, dipping, spraying, or hopper coating, among others. The oven baked resist is then cooled before the next operation.

2c. image the UV absorbing nano particles 104 on the photoresist layer 103 and stabilize the nano particle imaging if necessary by heat, photo, pressure, wind, solvent vapor or any suitable combination of available energy sources without damaging other substrate components. In some cases, the UV absorbing nano particle image can go to the next processing operation without any hard stabilizing process. Different from the photoresist polymers in that the UV absorbing nanoparticles generally do not exhibit a quick change in chemistry under UV exposure, the imaged UV absorbing nanoparticles thus become a mask for photoresist and replace the mask or recticle imaging step in the conventional photolithography. Similar to the process in FIG. 1, UV absorbing nano particles can be printed on the substrate 101 carrying the photoresist 103 by mechanisms such as inkjet head, dip pen lithography head, microcontact printing head, micromolding head, nano imprint head, charge transfer from photoconductor or irradiation energy induced electrostatic charge transfer to achieve the desired feature size.

2d. expose the photoresist layer 103 and the UV absorbing particles 104 with suitable light that is strongly absorbed by the resist materials. This exposure operation is maskless and is known as a blanket exposure.

2e. remove the UV exposed resist layer by suitable developer to achieve photo resist patterns for next step of processing of the substrate. In this case, any desired resist materials can be used to maintain a targeted etch profile of the substrate.

2f. After the etched pattern was obtained on the substrate, the photoresist and the UV absorbing nano particles can be removed

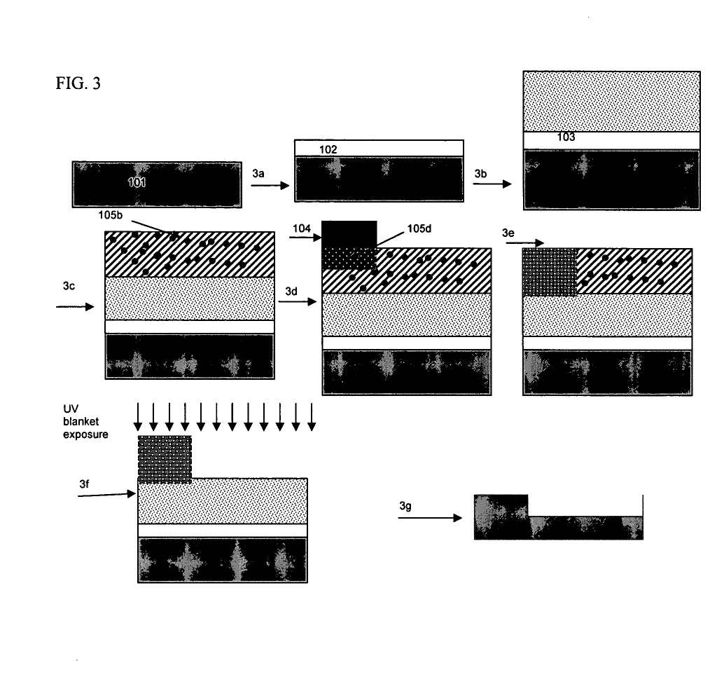

Turning now to FIG. 3, yet another process of maskless lithography using UV absorbing nano particles is shown. The process is as follows:

3a. coat the substrate 101 with adhesion promoter 102 as described above in either FIG. 1 or FIG. 2.

3b. coat the photosensitive layer 103 on the promoter 102 as described above in FIG. 2.

3c. overcoat the surface of the photo sensitive layer 103 with an aqueous solution of a water soluble thermoplastics 105b containing an immobilizing agent. This layer is stabilized by removal of coating solvent.

3d. image the UV absorbing nano particles 104 onto the photoresist layer 103. Similar to the process of FIG. 1, the UV absorbing nano particles can be printed onto the substrate carrying the photoresist by inkjet head, dip pen lithography head, microcontact printing head, micromolding head, nano imprint head, irradiation energy induced electrostatic charge transfer to achieve desired feature size. During the imaging operation, the UV absorbing nano particles (ink) penetrate into the water soluble thermoplastic layer 105b and are immobilized upon reaching an immobilizing agent 105d.

3e. develop the immobilized patterns 105d with an aqueous liquid to render a UV absorbing nano particle mask on the photoresist layer 103. The mask patterns are then stabilized by air or heat before the next operation 3f.

3f. blanket expose (as described in FIG. 2) the photoresist layer 103 and the UV absorbing particles 104 with a suitable light whose wavelength is strongly absorbed by the resist materials.

3g. develop the resist layer by suitable developer to achieve photo resist patterns ready for next step of substrate etching. After the substrate etching, the resist mask is removed to render etched patterns on the substrate.

The immobilizing agent 105b can be a chemical species which can react with the UV absorbing nano particles to form a film but does not react with water soluble thermoplastic media. The formed film remains on the surface of the photoresists to become a mask for patterning of the photoresist. Of course, without reacting with UV absorbing nano particles, the water soluble thermoplastic layer stays soluble and will be washed out by suitable aqueous solutions. The maskless lithography process can be done without operation 3e. However, operation 3e can be used to eliminate satellite ink drops from an inkjet head to achieve a sharply-cutted edge of UV absorbing nano particle patterns printed by inkjet head.

The immobilizing effect above mentioned is an interaction between a pair of large ions carrying opposite charge yielding a neutral species. In one embodiment, the immobilizing agents are selected from a group of specific ions such as (but not limited to) iodonium salts, phosphonium salts, carbonium salts, ammonium salts, sulfonium salts, sulfonic acid salts, and carboxylic acid salts, among others. The UV absorbing nano paticles are selected to carry counter ions having opposite charge against the charge on the immobilizing agent. The immobilizing effect can also be an interaction between a donor and an acceptor yielding a charge transfer complex. One example of immobilizing agent from donor molecules is polyethylene imine and the likes which can also easily form a complex with UV absorbing nano particles with accepting finctional groups such as acidic and salts groups.

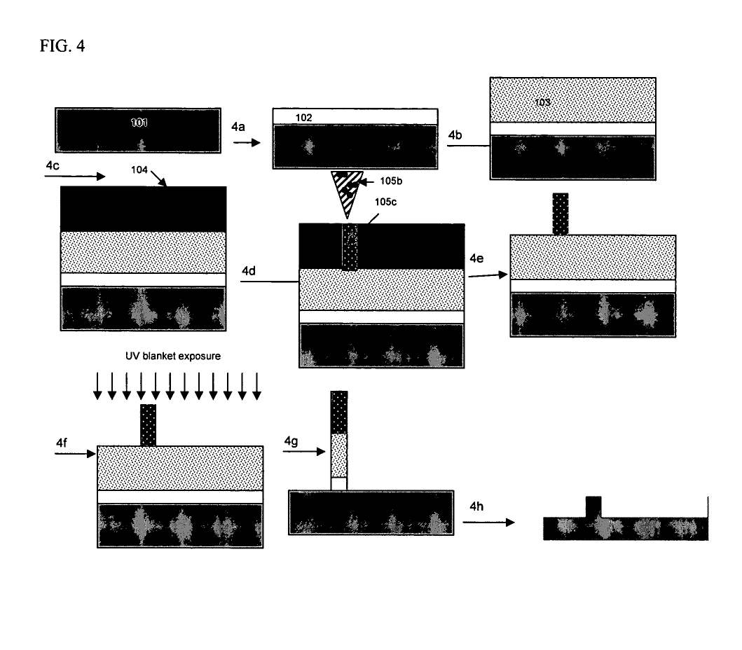

Turning now to FIG. 4, another exemplary process of maskless lithography using UV absorbing nano particles is shown with the following operations:

4a. coat the substrate 101 with adhesion promoter 102

4b. coat the photosensitive layer 103 on 102.

4c. overcoat the surface of the photo sensitive layer 103 by UV absorbing nano particles 104 and dry the combination

4d. image the water soluble thermoplastic media 105b containing immobilizing agent onto the UV absorbing nano particle 104. Similar to the process of FIG. 1, the imaging process can be digitally done using inkjet head, dip pen lithography head, microcontact printing head, micromolding head, nano imprint head, irradiation energy induced electrostatic charge transfer to achieve desired feature size. During the imaging process, the water soluble thermoplastic layer penetrates into the UV absorbing nano particles layer and form an immobilized pattern 105d.

4e. develop the immobilized patterns 105 with aqueous developer.

4f. perform a blanket exposure of the entire system

4g. develop the system to achieve nano patterns

4h. etch the substrate and remove the nano-mask to achieve a nano pattern etched substrate.

FIG. 5 shows the a fifth embodiment of the process of maskless lithography using UV absorbing nano particles. In this process, a water soluble thermoplastics coating is utilized to modulate the droplets. The process is as follows:

5a. coat the substrate 101 with adhesion promoter 102

5b. coat the photosensitive layer 103 on 102.

5c. overcoat the surface of the photo sensitive layer 103 with a water soluble thermoplastic 105a containing no immobilizing agent and dry the combination.

5d. image the UV absorbing nano particles 104 onto the water soluble thermoplastic layer 105a. As described above, the imaging process can be digitally done by inkjet head, dip pen lithography head, microcontact printing head, micromolding head, nano imprint head, irradiation energy induced electrostatic charge transfer to achieve desired feature size.

5e. perform a blanket exposure as described above.

5f. develop the system to achieve nano patterns mask

5g. etch the substrate and remove mask to achieve a nano pattern etched substrate.

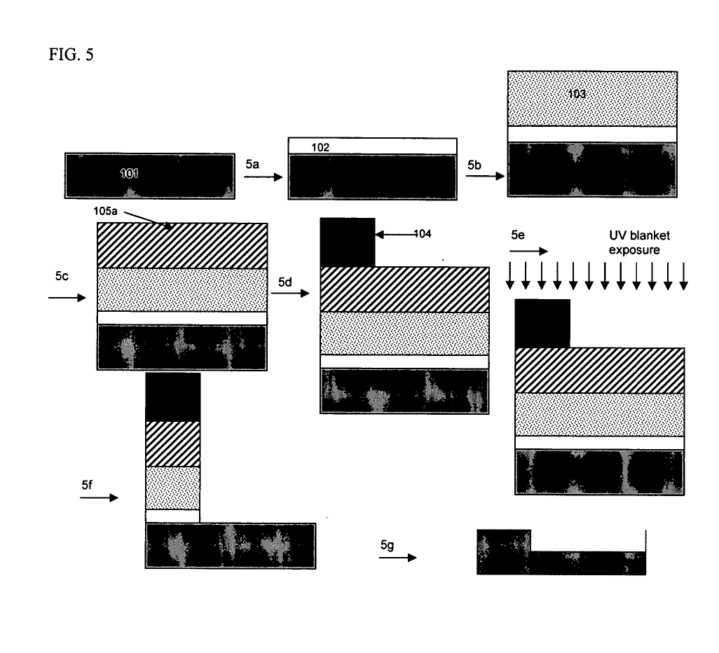

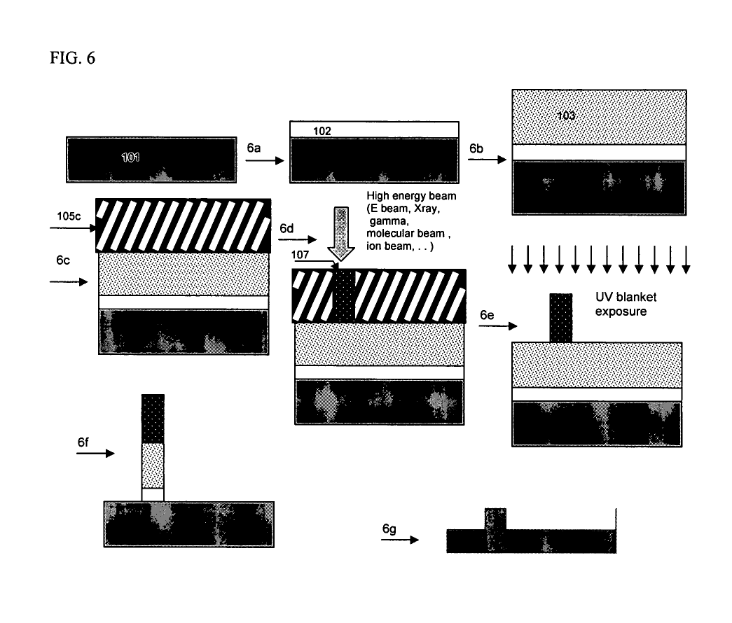

Referring now to FIG. 6, yet another embodiment of a process of maskless lithography using UV absorbing nano particles is shown. The process includes the following operations:

6a. coat the substrate 101 with adhesion promoter 102

6b. coat the photosensitive layer 103 on 102.

6c. overcoat the surface of the photo sensitive layer 103 by UV absorbing nano particle embedded into a water soluble thermo/photo-hardening media 105c and dry the combination.

6d. write the image onto the media 105c layer by an electron source beam or a high energy beam such as E beam, X ray, gamma, molecular beam, ion beam, among others. UV absorbing nano particles also adsorb the energy from the writing head and transfer it to the thermo/photo-hardening media to crosslink the particles in an embedded media 107. Afterwards, the image is developed by aqueous developer. Unexposed area is washed away and exposed area stays to achieve desired feature size which is nanometer in size

6e. perform blanket exposure as discussed above.

6f. develop the system to achieve nano patterns mask of photoresist.

6g. etch the substrate and remove mask to achieve nano pattern etched substrate

In the process of FIG. 6, water soluble thermo/photo-hardening media is albumin or albuminoid compounds. The hardening reaction occurs quickly to enhance the high energy beam writing speed compared to the conventional X ray, E beam lithography systems which are much slower due to the limits of sensitivity of current material such as PolyMethylMethacrylate (PMMA) or polyimide. The thermo/photohardenning media can be found from a group of compounds which can form intra or inter molecular hydrogen bonding such as polyaminoacids and its derivatives including protein products. The thermo/photohardenning media can also be found from a groups of polymeric materials which can crosslink under heat or light such as polycondensation products, free radical generating acrylic compounds. The thermo/photohardenning media can also be found from a groups of hydroxylated polymers such as phenolic resin, formaldehyde resin, polyvinyl butyral, polyvinyl alcohols. In the above described maskless lithography process, the thermohardening media can also be modified with photo/thermo-hardenning materials. The photo-effect of light is to help complete the cross linking reaction besides thermal effect due to high energy beam. The UV absorbing nano particles can also absorb the high energy and perform energy transfer between particles and media molecules. Examples of typical photo/thermo-hardening materials include egg albumin, water soluble hydroxy polymers including but not limited to poly vinyl alcohol (PVA), polyvinyl acetate (PVAc), poly vinyl butyral (PVB), poly vinyl aldehyde, poly vinyl acetal, poly vinyl imidazol, phenolic resin, formaldehyde resin.

In this case UV absorbing nano particles acts as sensitizer for the thermo-hardening reaction of the thermo/photo-hardening media. In the above mentioned process, media 105c acts as negative resist. If the UV absorbing nano particles are embedded in a hydrophobic polymer such as polyimide, PMMA, media 105c acts as a positive resist. In this case, exposed area becomes soluble and unexposed area stays after development. In some cases, UV absorbing nano particles can act as sensitizer for high energy beam lithography using conventional media such as PMMA, polyimide by embedding UV absorbing nano particles in such media. PMMA or polyimide media containing UV absorbing nano particles can be coated directly onto the substrate 101 in order to proceed substrate etching operation without using resist.

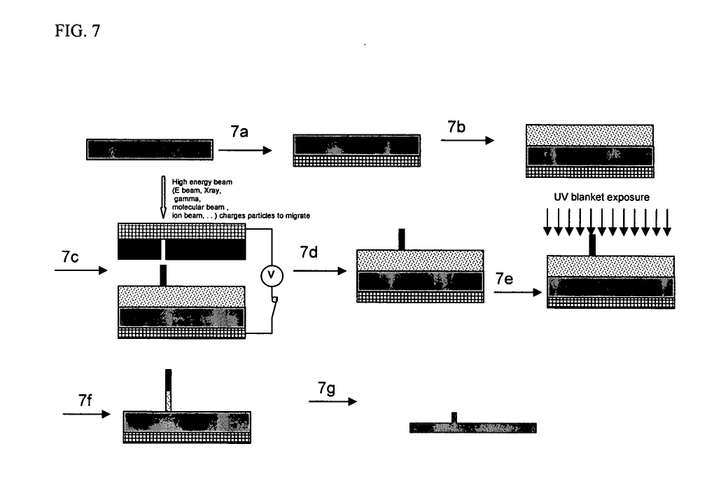

Turning now to FIG. 7, another embodiment of the process of maskless lithography using UV absorbing nano particles is shown. The process is as follows:

7a. deposit on the substrate 101 a metal to form an electrode 106

7b. coat the substrate 101 with the adhesion promoter 102 and then overcoat it with the photoresist 103.

7c. UV absorbing nano particles is coated with a thermoplastics/hydrophobic solvent onto another set of transparent electrode, and slightly dried. Then, an electric field is spontaneously applied together with the writing head from high energy sources such as X ray, E beam, ion beam, molecular beam, for example. The thermo energy causes the UV absorbing nano particles to become charged due to the thermo carrier and it. An electric field—induced particle migration to the opposite electrode causes the UV absorbing nano particles to be deposited onto the resist surface.

7d. stabilize the UV absorbing nano particles with solvents and energy, among others, to form a mask for photoresist having the desired feature size.

7e. perform blanket exposure

7f. develop the system to achieve nano patterns mask

7g. etch the substrate and remove mask to achieve nano pattern etched substrate.

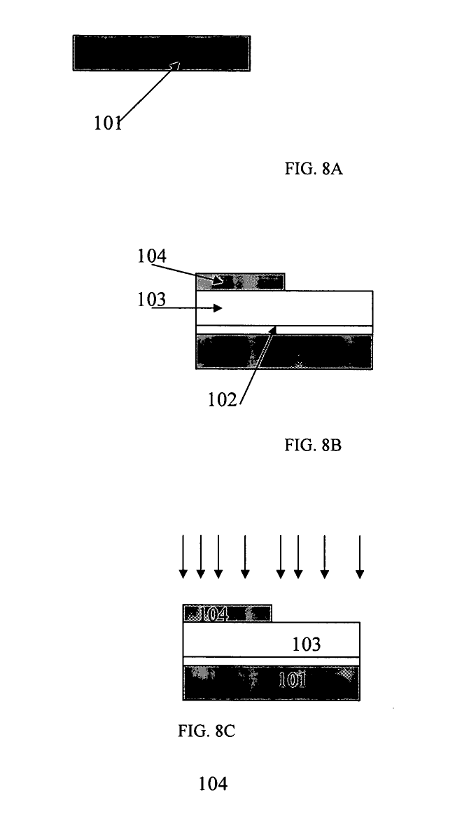

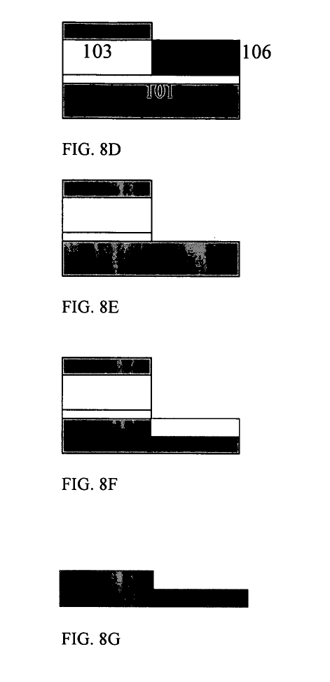

FIGS. 8A-8G show exemplary operations in another embodiment of a maskless lithography process using UV absorbing nano particles. FIG. 8A shows a substrate 101 that receives nano-particles in a maskless lithography process. In FIG. 8B, an adhesion promoter 102 is deposited to enhance adhesion between the layers and to minimize the chance that moisture or other impurities to penetrate the seams between the layers, causing corrosion or other impurity-induced phenomena that adversely impacts the performance of an integrated circuit. In FIG. 8B, a photosensitive layer 103 is formed. The photosensitive layer can be a positive or negative photo resist or photoconductor. A nano-particle image 104 is formed above the photosensitive layer 103. The image can be formed digitally through suitable printing or jetting methods inkjet head, dip pen lithography head, microcontact printing head, micromolding head, nano imprint head, irradiation energy induced electrostatic charge transfer or writing head from high energy sources such as X ray, E beam, ion beam, molecular beam to achieve desired feature size from 1 nm.

In some cases, the imaging can be done by writing the substrate carrying UV absorbing nano particles with a suitable energy source. In FIG. 8C, the nano particle image can be exposed to radiation, i.e., UV, X-ray, electron beam, or the like. After exposure to radiation, the photosensitive portion not covered by the nano-particle image 104 is experiencing a chemical change. The photosensitive layer is a positive photoresist and the exposed photosensitive portion is washed away to form the exemplary structure of FIG. 8E. Next, the substrate 101 is etched in FIG. 8F, and the nano-particle image 104, the photosensitive layer 103, and the adhesion promoter 102 are removed, leaving the semiconductor structure of FIG. 8G.

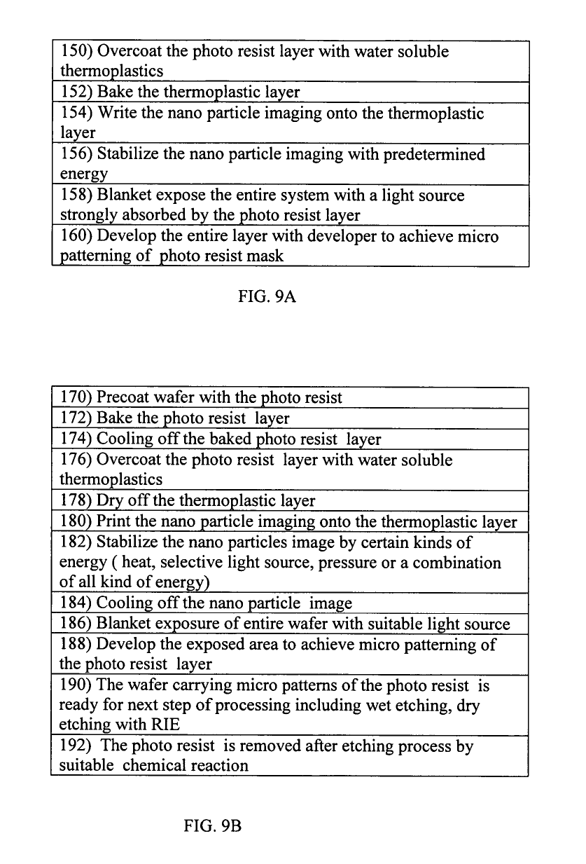

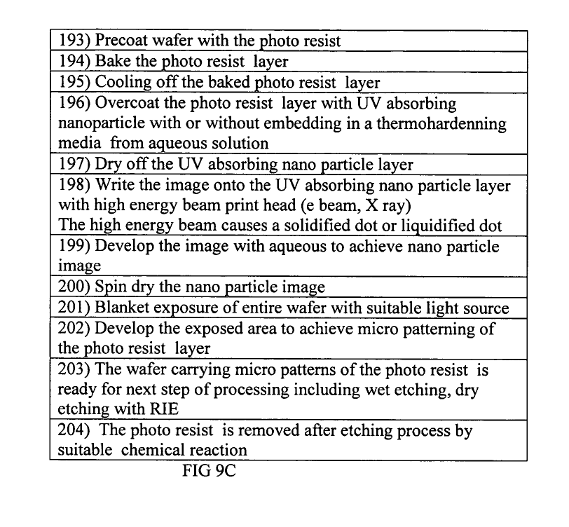

FIGS. 9A and 9B show two embodiments of a process for performing maskless lithography. A substrate can be initially coated with a film comprising the photo resist composition dissolved in a suitable solvent. The substrate may or may not be coated with an organic anti-reflective layer prior to deposition of the resist composition. Alternatively, a bilayer substrate may be employed wherein a resist composition forms an upper resist layer (i.e., the imaging layer) on top of a bilayer substrate comprised of a base layer and underlayer that lies between the upper resist layer and the base layer. The base layer of the bilayer substrate is comprised of a suitable substrate material, and the underlayer of the bilayer substrate is comprised of a material that is highly absorbing at the imaging wavelength and compatible with the imaging layer. Conventional underlayers include cross-linked poly(hydroxystyrene), polyesters, polyacrylates, fluorinated polymers, cyclic-olefin polymers and the like, including diazonapthoquinone (DNQ)/Novolak resist material. The surface of the coated or uncoated, single or bilayer substrate is cleaned by standard procedures before the film is deposited thereon. Suitable solvents for the composition are as described in the preceding section, and include, for example, cyclohexanone, ethyl lactate, and propylene glycol methyl ether acetate. The film can be coated on the substrate using art-known techniques known in the art, such as spin or spray coating, or doctor blading. The substrate is then ready for maskless lithography.

Turning now to FIG. 9A, one exemplary process for maskless lithography is shown. In 150, the process overcoats a photoresist layer with water soluble thermoplastics. Next, in 152, the thermoplastic layer is baked at an elevated temperature of about 30-90 C for a short period of time, typically on the order of about 0.1-60 minutes. The dried film has a thickness of about 0.01 to about 100 microns. In 154, the process writes the UV absorbing nano-particle imaging onto the thermoplastic layer.

The nano-particle imaging can be done using inkjet printing including thermal inkjet, piezoelectric inkjet, continuous inkjet, electrostatic printing, ion flow printing, electric field assisted dry inkjet, heat and or photo-induced charged particle migration, dip pen lithography and nanoimprint lithography. For example, neutral nano particle well dispersed in an insulating fluid can generate a charge by absorbing thermal, photon energy from a high energy print head such as e-beam or X-ray and migrate to opposite site under application of an electrical bias, as reported as the particle migration imaging, published in Seybold Report on Publishing Systems, Vol 23 No 6, the content of which is incorporated by reference. The UV absorbing nano particles can be incorporated into a fluid to form a liquid ink which can be digitally printed out by asingle head or by a print head array of thermal ink jet or by a piezoresistive ink jet print head carrying multi-nozzles. The selection of fluid in the ink formulation can optimize the stable droplet from the selected print head and onto the photoresist surface. Alternatively, charged UV absorbing nano-particles can be transferred from photoconductor onto semiconductor wafer carrying the photosensitive layer. The UV absorbing nano particles can also be transferred onto the photosensitive layer by soft lithography including microcontact printing, nano molding techniques(see Scientific American September 2001, page 42, the content of which is incorporated by reference)

In 156, the nano-particle image is stabilized with a predetermined dose of energy. Next, in 158, the process exposes the entire system with a light source that is strongly absorbed by the photoresist layer. Further, in 160, the process develops the entire layer with a suitable developer to achieve micro-patterning of the photoresist mask.

Referring now to FIG. 9B, another exemplary process for maskless lithography is shown. In 170, the wafer is pre-coated with the photoresist. In 172, the photoresist layer is baked and in 174, the baked photoresist layer is cooled. Next, in 176, the photoresist layer is over coated with water soluble thermoplastics. In 178, the thermoplastic layer is dried off. Next, in 180, nano particles are imaged or printed onto the thermoplastic layer. In 182, the nano-particle image is stabilized using a suitable form of energy, for example heat, selective light source, pressure or a combination of suitable energy. In 184, the nano-particle image is cooled off and in 186, the process performs a blanket exposure of entire wafer with a suitable light source. In 188, the exposed area is developed to achieve micro-patterning of the photo resist layer. Inn 190, the wafer carrying micro patterns of the photo resist is ready for next step of processing including wet etching, dry etching with RIE or with KOH, TMAH. In 192, the photo resist is removed after etching process by suitable chemical reaction.

The photo resist may be a negative or a positive photo resist and other components and additives may also be present. The photo resist composition will usually be a chemically amplified photo resist. However, the present method will also work in non-amplification resist systems that utilize a photo acid so long as there is a sufficient delay between the exposure and the deblocking or cross linking activity of the photo acid. If the photo resist is a positive photo resist, the composition may include a monomeric or polymeric acid-cleavable dissolution inhibitor. When pattern wise exposed to a radiation source, the acid generated by the radiation-sensitive acid generator will cleave the acid-cleavable moieties in the resist binder and/or in the dissolution inhibitor, thus making the exposed areas of the photo resist composition soluble in conventional developer solutions.

Suitable dissolution inhibitors will be known to those skilled in the art and/or described in the pertinent literature. Preferred dissolution inhibitors have high solubility in the resist composition and the solvent used to prepare solutions of the resist composition (e.g., propylene glycol methyl ether acetate, or “PEGMEA”), exhibit strong dissolution inhibition, have a high exposed dissolution rate, are transparent at the wavelength of interest, exhibit a moderating influence on Tg, strong etch resistance, and display good thermal stability (i.e., stability at temperatures of about 140° C. or greater). Both polymeric and monomeric dissolution inhibitors may be used in the photo resist composition.

Suitable dissolution inhibitors include, but are not limited to, bisphenol A derivatives and carbonate derivatives wherein the hydroxyl group of bisphenol A is replaced by tert-butyl derivative substituents such as tert-butyloxy, tert-butyloxycarbonyl, and tert-butyloxycarbonyl-methyl groups; fluorinated bisphenol A derivatives such as CF₃-Bis-A/tBuOCOCH₃(6F-Bisphenol A protected with a t-butoxycarbonylmethyl group); normal or branched chain acetal groups such as 1-ethoxyethyl, 1-propoxyethyl, 1-n-butoxyethyl, 1-isobutoxy-ethyl, 1-tert-butyloxyethyl, and 1-tert-amyloxyethyl groups; and cyclic acetal groups such as tetrahydrofuranyl, tetrahydropyranyl, and 2-methoxytetrahydropyranyl groups; androstane-17-alkylcarboxylates and analogs thereof, wherein the 17-alkylcarboxylate at the 17-position is typically lower alkyl. Examples of such compounds include lower alkyl esters of cholic, ursocholic and lithocholic acid, including methyl cholate, methyl lithocholate, methyl ursocholate, t-butyl cholate, t-butyl lithocholate, t-butyl ursocholate, and the like; hydroxyl-substituted analogs of such compounds (ibid.); and androstane-17-alkylcarboxylates substituted with 1 to 3 C₁-C₄ fluoroalkyl carbonyloxy substituents, such as t-butyl trifluoroacetyllithocholate (see, e.g., U.S. Pat. No. 5,580,694 to Allen et al., the content of which is incorporated by reference).

If the photo resist composition is a negative photo resist, the composition will include a cross linking agent. When exposed to radiation, the acid produced by the radiation-sensitive acid generator in the exposed areas will cause the cross linking agent to react with the polymers of the invention, thus making the exposed regions insoluble in developer solution. Dissolution inhibitors are not included in negative photo resists nor are cross linking agents included in positive photo resist.

The UV absorbing nanoparticle image can be exposed to radiation, i.e., UV, X-ray, electron beam, or the like. If ultraviolet radiation is used, ultraviolet radiation having a wavelength of about 248 nm, 193 nm, 157 nm or less than 157 nm can be used. Suitable radiation sources include mercury, mercury/xenon, and xenon lamps. Conveniently, due to the enhanced radiation sensitivity of the photo resist composition, full exposure of the photo resist composition is achieved with low dosage of radiation. If electron beam radiation is used, full exposure of the photo resist composition is achieved with less than about 25 uC/cm2. The exact exposure required will, of course, be highly dependent on the radiation source and the resist materials.

Other potential exposure sources include, but are not limited to, conventional projection or contact/proximity printing with wavelengths such as arc lamp lines and laser sources; extreme ultraviolet radiation (EUV) and other x-ray point sources, synchrotron and undulator sources; particle beam sources such as electrons and ions; and exposure methods associated with emerging maskless lithography techniques (such as scanning probes with optical, electrical, thermal, and mechanical effects). The trend toward lithographic methods wherein the exposure does not penetrate throughout a resist layer renders the method described herein increasingly significant. The image is developed with a suitable solvent including an aqueous base, preferably an aqueous base without metal ions such as the industry standard developer tetramethyl-ammonium hydroxide or choline. In positive photo resist applications, the exposed areas of the photo resist will be soluble, leaving behind the unexposed areas. In negative photo resist, the converse is true, i.e., the unexposed regions will be soluble to the developer while the exposed regions will remain. The wafer carrying micro patterns of the photo resist is ready for next step of processing including wet etching with, dry etching with RIE. The photo resist is removed after etching process by suitable chemical reaction Thus, the method and apparatus of the invention can be used to create patterned material layer structures such as metal wiring lines, holes for contacts or vias, insulation sections (e.g., damascene trenches or shallow trench isolation), trenches for capacitor structures, etc. as might be used in the design of integrated circuit devices.

Turning now to a current trend, a fullerene which has received attention as new carbon is, chemically, a transformation of carbon black. Comparing the former with the latter with respect to a micro structure; the latter is formed by stacking an infinite honeycomb-shaped network plane at uniform intervals in parallel regularly in three-dimensions; contrary to this, in the case of the former a closed minimum unit system corresponding to a molecule can be strictly defined and the individual system is composed of, in principle, polyhedron-type network comprising arbitrary number of hexagon and 12 pentagons. For such a unique structure, the fullerene has been investigated as a new material of the twenty-first century in each field and it has been expected that the fullerene can be applied in a wide variety of fields from a superconductor, semiconductor and nonlinear optical material down to new type fuel and novel pharmaceutical active substances.

Form of the fullerene can be divided into spherical-type and tube-type. And mono layer-type and multi-layer type are known in each type. An active basic research has been developed everywhere in the world on C60, C70 and mono-layer and multi-layer carbon nano-tubes as objects. Papers of 13,000 and above have been printed and published from 1990 and 1991 when these two forms of fullerene carbon has been isolated for the first time up to the present time.

As discussed in U.S. Pat. No. 6,692,718, the content of which is incorporated by reference, the fullerene is included in specific soot, that is, fullerene black obtained by subjecting a graphite electrode to arc-discharge or irradiating graphite with laser in an inactive atmosphere such as helium and so on to vaporize carbon, cooling slowly and aggregating. The form of the fullerene is generally as follows: Mono-layer sphere—Fullerene in a narrow sense shown by the general formula Cn, While C60 and C70 are representative for Cn., the arc many cases where 76<n<100 is called as “higher fullerene” or 76<n<100 is called “giant fullerene.” The higher fullerene is soluble in an organic solvent and can be extracted and isolated from the fullerene black. C60 is a true sphere having a diameter of 0.7, but the remainder is an ellipsoidal sphere or polyhedron. Multi-layer sphere—Concentric multi-layer polyhedron particles having a small cavity therein exist in the fullerene black, which are called as “carbon nano-particle.” Mono-layer tube-type—This takes the form that a mono-layer fullerene is divided into two equal parts and a small wound graphite plate is inserted between them and connected. This can be formed by mixing a certain kind of metal catalyst with graphite by means of arc discharging method to vaporize, which is called as “mono-layer carbon nano-tube.” Multi-layer tube-type—This has the structure that several or tens layers of mono-layer carbon nano-tubes having different thicknesses are stacked concentrically. This can be formed in a residue of cathode by arc-discharge on a graphite electrode without a catalyst. In the multi-layer sphere fullerene of the above-described fullerenes, the true sphere-type having no excess space therein has been discovered other than the above-described polyhedron type having a cavity therein. That is to say, if the fullerene black is irradiated with a concentrated electron beam in an electron microscope, a polyhedron-type carbon nano-particle contained therein changes to a substantial true sphere-type multi-concentric structure having no cavity therein. This product is called as “carbon nano-onion.” Since the carbon nano-onion shows substantially perfect sphere, it has been expected to have more interesting performance than the polyhedron-type carbon nano-particle, and it is called as “ultimate fullerene.” In one embodiment, the foregoing exists as solids rather than as liquids.

UV absorbing nano particles for maskless lithography are preferably liquid nano form of carbon having hydrophilic functional groups attached thereto. The hydrophilic funtional groups attached thereto nano particles are selected from hydrophilic substituent groups of inorganic and/or organic acid, base, acid salts, base salts, water soluble anchoring containing but not limited to glycol ethylene, imines, imidazol derivatives with and without subsituents selected from alkyl, alkenes, aromatic with and/or without —OH, —SH, —CH2OH, —NO2, —NH2, —COOR, —CN,halogene substitute, acrylic substitute. The fluid utilized to form the liquid nano particles are selected from solvents having high polarity such as water.

The UV absorbing nano particles above mentioned are the liquid nano carbon having hydrophobic fuctional groups attached thereto. In this case, the anchoring hydrophobic group makes the particle more “dispersed” in hydrophobic fluid due to the solvation effect. The hydrophobic functional groups attached thereto nano carbon particles are selected from hydrophobic substitute groups of alkyl, alkenes, aromatic with and/or without —OH, —SH, —CH2OH, —NO2, —NH2, —COOR, —CN,halogen substitute, acrylic substitute. The fluid utilized to form the liquid nano particles are selected from organic solvents having low polarity with long alkyl chain such as isoparafin products available from Exxon. Spin coating of liquid nano carbon particles dispersed in hydrophobic solvent over the hydrophobic surface of a photo resist substrate may dissolve the substrate. In this case, the long alkyl chain hydrocarbon solvents tends to minimize the solubility and maintain the good interface between top layer of UV absorbing nano particles and the photo resist layer under the beneath In some case, a solvent barrier layer may be used to prevent the penetration of the top coating into the bottom layer. The solvent barrier in this case is made out of water soluble thermoplastics.

The raw materials which can use to form liquid nano carbon are selected from carbon nano tube (such as those available from Zyvek), fullerene particles, graphite, graphene, carbon black, coal, charcoal or any combustion products of unsaturated hydrocarbon, combustion products of cellulose, combustion products of diesel oil, mazut oil, rubber tire. The raw materials can also be inkjet colorant such as water dispersive carbon black products known in the market by Cabot, Degussa, Rohm and Haas, Orient Chemical, and, Dupont, among others.

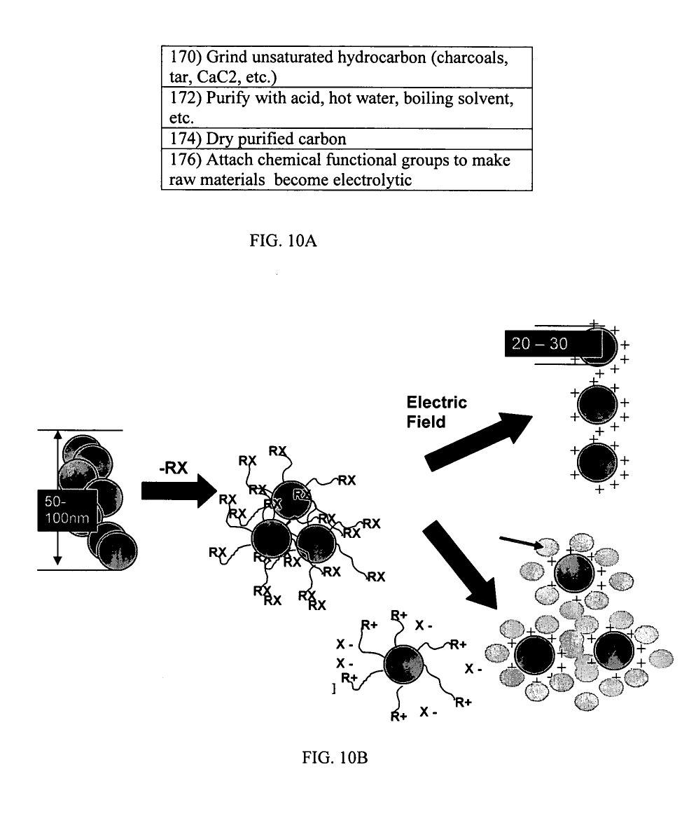

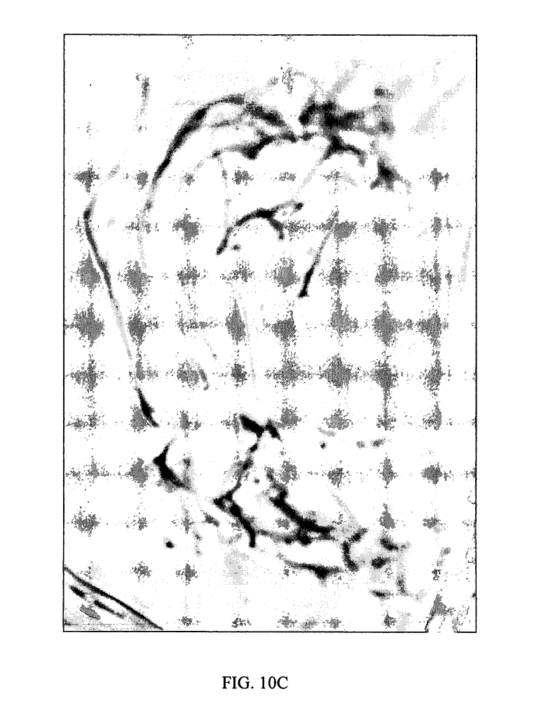

Turning now to FIG. 10A, a process to form a hydrophilic liquid nano-particles is shown. In 170, the process includes grinding raw materials (charcoals, tar, CaC2, etc.) into small particles. In 172, the grinded micro-particles are purified with acid, hot water with and without surfactant, boiling solvent, among others. Next, the purified product is dried. Further, in 176, chemical finctional groups are attached using conventional known techniques such as those disclosed in The Chemical Educator, Vol. 5, No. 2, S1430-4171(00)02374-7, 10.1007/s00897990374a, © 2000 Springer-Verlag New York, Inc., the content of which is incorporated by reference, to make raw materials become electrolytic.

FIG. 10B shows an image of a process to generate liquid carbon nano-particles. First, carbon particles of approximately 0.4 nm-100 nm in size are finely grinded and purified first in hot water containing surfactant, secondly, refluxed in hydrocarbon solvents (toulene, benzene or the likes), then in heated Nmethyl Pyrrolidone (NMP) When they are stirred in a aqueous fluid with a aromatic amine containing —RX functional groups, the —RX functional groups attach to the aromatic ring of the raw materials based on the known chemical reaction called diazo coupling described in Organic Chemistry, published by Fisher 1975 or in The Chemical Educator, Vol. 5, No. 2, S1430-4171(00)02374-7, 10.1007/s00897990374a, © 2000 Springer-Verlag New York, Inc. Due to the same sign charge repulsion, the functional groups evenly distribute themselves when immersed in an electrolytic liquid, or when an electric field is applied. the nano particles of carbon can be isolated by a fast spinning of liquid nano carbon on a substrate following fast removal of fluid by heating effect. The charged nano perticles of carbon can be isolated by an electric field following heating effect. The heating temperature is little above the boiling point of fluid

FIG. 10C shows a microphotograph of the liquid carbon nano-particles. As shown therein, the nano-particles form branches that resemble neurons.

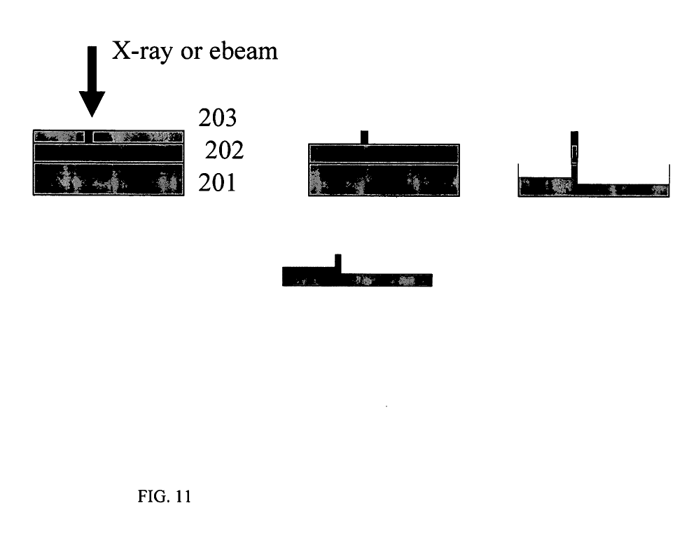

FIG. 11 shows another exemplary process to perform maskless lithography. In FIG. 11A, a substrate 201 provides a base on which a photo resist layer 202 is formed. Next, a nano-particle layer 203 is formed above the photo resist layer 202. The nano-particle layer 203 is dispersed within a thermo hardening media compatible with fluid utilized for coating of UV absorbing nano particles. Upon an application of high energy beams such as X-ray, e-beam, heat or energy, the nano-particle 203 absorbs the energy and transfer it into the disperse media to convert it into insoluble (hardenning process). The remaining nano-particle pattern can be washed away. Then photo resist layer 202 and the nano-particle layer 203 can then be removed. Further, portions of the substrate 201 can be etched to leaved a desired substrate geometry. In this case, small features below sub micron is easily achieved without using mask and the lithographic system is still beneficial from the excellent etch resistance of the photo resist mask Also, some nano particles such as carbon serve as sensitizer for thermohardenning process and it does effectively reduce the writing time, significantly enhance the production throughput.

In the above described maskless lithography process, the thermohardening media can also be modified with photo/thermo-hardenning materials. The photo-effect of light is to help complete the cross linking reaction besides thermal effect due to high energy beam. The UV absorbing nano particles can also absorb the high energy and perform energy transfer between particles and media molecules. Examples of typical photo/thermo-hardening materials include egg albumin, water soluble hydroxy polymers including but not limited to poly vinyl alcohol (PVA), polyvinyl acetate (PVAc), poly vinyl butyral (PVB), poly vinyl aldehyde, poly vinyl acetal, poly vinyl imidazol, phenolic resin, formaldehyde resin.

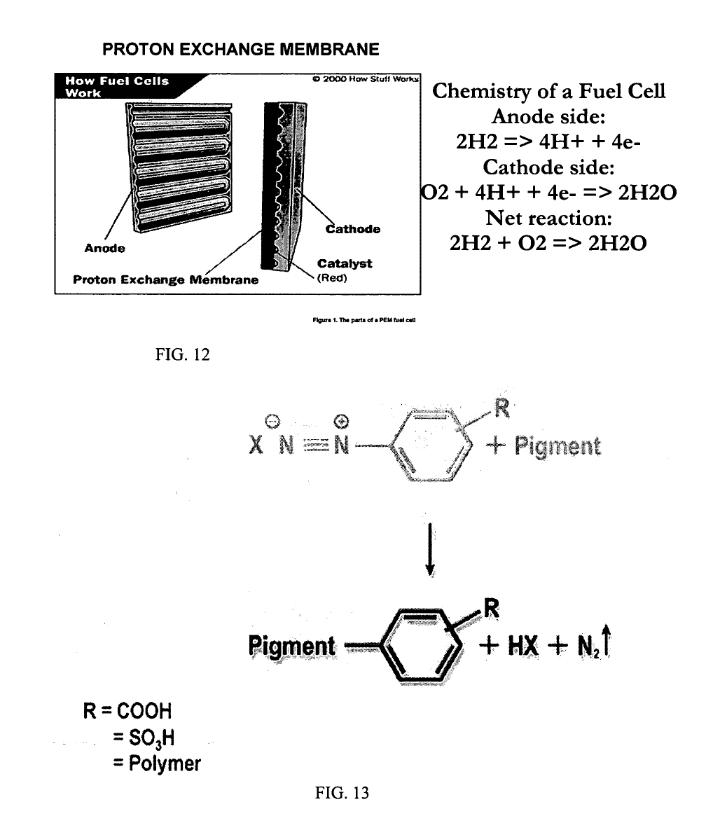

FIGS. 12-13 shows an exemplary process for making a fuel cell using a liquid nano carbon. In FIG. 12, the system sputters or electroplates Platinum or any catalyst which can strongly absorb hydrogen. Next, the process spin-coats specific liquid nano carbon onto the surface of catalyst. The liquid nano-carbon works as proton exchange membrane, —SO3H, —SO3Na, —SO3K, among others.

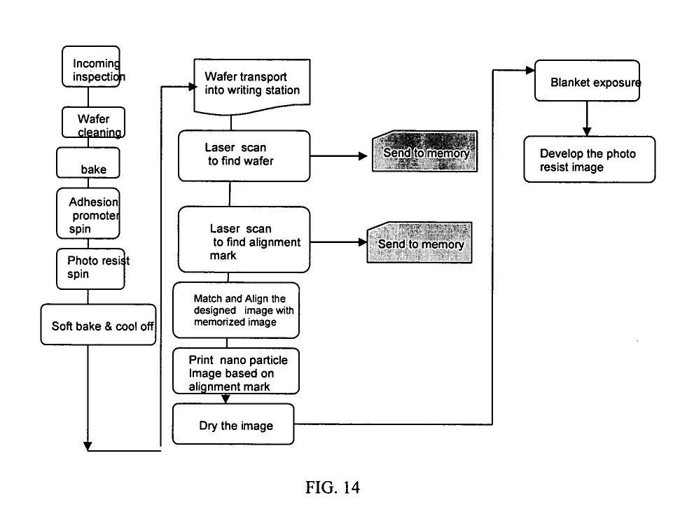

FIG. 14 illustrates an exemplary process for printing nano-particles on a substrate or a wafer. In general, the equipment for maskless lithography can include a digital camera or other imaging equipment that scans a wafer to find and memorize the position of alignment marks. Next, a computer with suitable software matches a mask design image onto the wafer. Next, a designed image is printed on the wafer. The digital printing can be done by inkjet(piezo, thermal) print head, thermal print head, laser print head, nano-imprint transfer process, e beam, X-ray, and gamma rays, among others.

Turning now to FIG. 14, the wafer is initially inspected in an incoming inspection operation. Next, the wafer is cleaned. The wafer is then baked. An adhesion promoter is spin-coated on the wafer. Next, a photo-resist layer is spin-coated on the wafer. The combination is soft-baked and allowed to cool.

The processed wafer is then transported into a writing station or chamber. A scan is performed to determine the wafer position. The scan can be performed by a laser scanner, among others. A computer receives the scan and finds one or more alignment marks on the wafer. The computer matches and aligns a designed image with the scanned image of the wafer. Once the designed image is aligned with the wafer, the print process begins.

A print head prints the designed image with nano particles based on the aligned mark. The image is then dried. A blanket exposure operation is performed as discussed above, and the photo-resist image is then developed.

The invention has been described in terms of specific examples which are illustrative only and are not to be construed as limiting. The invention may be implemented in digital electronic circuitry or in computer hardware, firmware, software, or in combinations of them. Apparatus of the invention may be implemented in a computer program product tangibly embodied in a machine-readable storage device for execution by a computer processor; and method steps of the invention may be performed by a computer processor executing a program to perform finctions of the invention by operating on input data and generating output. Suitable processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (Asics) or suitably programmed field programmable gate arrays (FPGAs).

From the a foregoing disclosure and certain variations and modifications already disclosed therein for purposes of illustration, it will be evident to one skilled in the relevant art that the present invention can be embodied in forms different from those described and it will be understood that the invention is intended to extend to such further variations. While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

1. A maskless lithography process, comprising:
over coating a photo resist layer with water soluble thermoplastics; and
imaging ultraviolet (UV) absorbing nano particles onto the photo resist layer.

2. The process of claim 1, wherein the water soluble thermoplastic layer comprises one of: a pure thermoplastic without additives, a contrast enhancement material; a thermoplastics containing immobilizing agent selected from a group of chemical species carrying opposite charge with ion located on UV absorbing nano particle surface; and a thermoplastics containing an immobilizing agent selected from a group of chemical species forming a electron acceptor/donor complex with UV absorbing nano particles.

3. The process of claim 2, wherein the immobilizing agent comprises one of a phosphonium salt and polyethyleneimine.

4. The process of claim 1, wherein the imaging further comprises UV absorbing nano particles embedded in a photo/thermo-hardening media.

5. The process of claim 4, wherein the photo/thermo-hardening media comprises one of a heat and a photo-induced hydrogen bonding forming compound.

6. The process of claim 5, wherein the photo/thermo hardening media is one of albumin and albuminoid compounds.

7. The process of claim 1, wherein the imaging further comprises UV absorbing nano particles embedded in an X-ray induced dissolving media.

8. The process of claim 1, wherein the UV absorbing nanoparticle comprises one of a chemically modified carbon nanotube, fullerene C60, fullerene C70, graphite, graphene, carbon black, iron oxide (Fe2O3, Fe3O4), Titanium oxide (TiO2), Cobalt Oxide, Zinc Oxide, Magnesium Oxide, Aluminum OxideAl2O3, Aluminum Hydroxide AlO(OH), Silicon Dioxide, Zirconium Oxide, contrast enhancement molecules, UV prohibiter molecules, sun block molecules, or a nano catalyst to form UV blocking molecules under irradiation of light or heat.

9. The process of claim 1, wherein the UV absorbing nanoparticles comprise carbon having specific chemical functional group specified as XR1 (1) in which
R1=—COO—, —SO3-, —CH2CH2O—, —CF2CF2O—, —O—, —S—, —NH4-, alkyl, aryl, alkenes, aryl alkyl carrying with or without the above functional groups (—COO—, —SO3-, —CH2CH2O—, —CF2CF2O—, —O—, —S—, —NH4-, —NO2, —NH2)
R1=H, metal ions,—OH, halogen and halogen ions, alkyl, aryl, alkenes, aryl alkyl with and without substitute groups selected from —COO—, —SO3-, —CH2CH2O—, —CF2CF2O—, —O—, —S—, —NH4-, H, Metal ions, —OH,halogen and halogen ions
R2 (2) represents organic and inorganic acid salts including pyrilium salts, phosphonium salts, carbonium salts, ammonium salt, sulfonium salts, carboxylic acid salts, boric acid salts, phosphoric acid salts, hydrochloric acid salts, or perchloric acid salts.

10. The process of claim 1, wherein the imaging further comprises performing one of the following: drop-on-demand inkjet printing, continuous inkjet printing, electron source—induced hardening, dissolving, high energy beam—induced hardening, dissolving, high energy beam—induced charged particle migrating; electrostatic transferring of charged nano particle imaging; thermo-plasticizing induced nano particles transfering, dip pen lithographic inking of UV absorbing nano particles, microcontact printing, micromolding, nano imprinting, or irradiation energy induced electrostatic charge transferring to achieve a desired feature size.

11. The process of claim 1, comprising high energy beam hardening using one of E-beam, X-ray, Gamma ray, MBE beam, ion beam, and laser beam.

12. The process of claim 1, comprise stabilizing the imaged nanoparticle using a predetermined energy.

13. The process of claim 1, comprising exposing the photo resist layer with a light source strongly absorbed by the photo resist layer.

14. The process of claim 1, comprising developing the photo resist layer with a developer to micro-pattern the photo resist mask.

15. The process of claim 1, wherein the UV absorbing nanoparticle comprises a carbon particle having a particle size smaller than 100 nm.

16. The process of claim 1, wherein the UV absorbing nanoparticles comprise one of organic dyes, organic and inorganic pigments having particle size smaller than 100 nm.

17. The process of claim 1, wherein the UV absorbing nano particle comprises a polymer particle having a particle size smaller than 100 nm including one of emulsified latex polymer, core-shell polymer, and UV absorbing molecules embedded into polymer particles.

18. The process of claim 13, wherein the dissolving media comprises one of PMMA, polyimide, and gelatin.

19. The process of claim 1, wherein the photo resist layer comprises one of: a positive material and a negative material.

20. The process of claim 1, comprising depositing on a substrate including one of: a semiconductor wafer, a metal wafer, a glass wafer, a flexible plastic wafer and a rigid plastic wafer.

21. The process of claim 1, comprising imaging a UV absorbing nanoparticle onto the photosensitive layer.

22. The process of claim 17, comprising producing UV absorbing nano particles of carbon from one of: unsaturated hydrocarbon products, coconut oil, crude oil, coal, charcoal, mazut oil, peanut oil, diesel oil, rubber, terpentine oil and cellulose.

23. The process of claim 1, comprising imaging a pattern using nano particles of combustion products from one of unsaturated hydrocarbon products, coconut oil, crude oil, coal, charcoal, mazut oil, peanut oil, diesel oil, rubber, terpentine oil and cellulose.

24. The process of claim 1, comprising imaging a pattern using UV absorbing nano particles of plasma CVD products from one of: unsaturated hydrocarbon products, coconut oil, crude oil, coal, charcoal, mazut oil, peanut oil, diesel oil, rubber, terpentine oil and cellulose.

25. The process of claim 1, comprising imaging a pattern using UV absorbing nano particles of laser ablation products from one of: unsaturated hydrocarbon products, coconut oil, crude oil, coal, charcoal, mazut oil, peanut oil, diesel oil, rubber, and cellulose.

26. The process of claim 1, comprising imaging a pattern using UV absorbing nano particles of sol-gel products of one of: iron oxide (Fe2O3, Fe3O4), Titanium oxide (TiO2), Cobalt Oxide, Zinc Oxide, Magnesium Oxide, Aluminum OxideAl2O3, Aluminum Hydroxide AlO(OH), Silicon Dioxide, and Zirconium Oxide.

27. The process of claim 1, comprising imaging a pattern using one of: charged nano particles, nano-molding and heat/photo induced electrophoresis particles.

28. The process of claim 1, wherein the UV absorbing nanoparticles comprise carbon having specific chemical functional group specified as XR1 (1) in which
R1=—COO—, —SO3-, —CH2CH2O—, —CF2CF2O—, —O—, —S—, —NH4-, alkyl, aryl, alkenes, aryl alkyl carrying with or without the above functional groups (—COO—, —SO3-, —CH2CH2O—, —CF2CF2—, —O—, —S—, —NH4-, —NO2, —NH2)
R1=H, metal ions, —OH, halogen and halogen ions, alkyl, aryl, alkenes, aryl alkyl with and without substitute groups selected from —COO—, —SO3-, —CH2CH2O—, —CF2CF2O—, —O—, —S—, —NH4-, H,Metal ions, —OH, halogen and halogen ions;
R2 (2) represents organic and inorganic acid salts comprising pyrilium salts, phosphonium salts, carbonium salts, ammonium salt, sulfonium salts, carboxylic acid salts, boric acid salts, phosphoric acid salts, hydrochloric acid salts, or perchloric acid salts, and
wherein the carbon nano particles comprises a proton exchange membrane for a fuel cell.
